(19) United States
(12) Patent Application Publication
(10) Pub. No.: US 2025/0142920 A1
(43) Pub. Date: May 1, 2025

(54) STRUCTURE AND FORMATION METHOD OF SEMICONDUCTOR DEVICE WITH CONDUCTIVE CONTACT

(71) Applicant: Taiwan Semiconductor Manufacturing Company, Ltd., Hsinchu (TW)

(72) Inventors: Yi-Ren CHEN, Taoyuan City (TW); Che-Chia CHANG, Hsinchu City (TW); Po-Cheng CHI, Taoyuan City (TW); Yi-Hsin TING, Pingtung County (TW)

(21) Appl. No.: 18/493,949

(22) Filed: Oct. 25, 2023

(51) Int. Cl. H01L 29/66; H01L 21/8234; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/118; H10D 84/0135; H10D 84/0147; H10D 84/0149; H10D 84/038

(57) ABSTRACT

A semiconductor device structure and a method for forming a semiconductor device structure are provided. The method includes forming a metal gate stack wrapped around multiple semiconductor nanostructures, and the semiconductor nanostructures are adjacent to an epitaxial structure. The method also includes forming a dielectric layer over the metal gate stack and the epitaxial structure and partially removing the dielectric layer to form a contact opening exposing the epitaxial structure. The method further includes forming a first protective layer over sidewalls of the contact opening and forming a second protective layer over the first protective layer. The first protective layer has a lower dielectric constant than that of the second protective layer. In addition, the method includes forming a conductive contact over the second protective layer and the epitaxial structure to fill the contact opening.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2K are cross-sectional views of various stages of a process for forming a portion of a semiconductor device structure, in accordance with some embodiments.

FIGS. 3A-3P are cross-sectional views of various stages of a process for forming a portion of a semiconductor device structure, in accordance with some embodiments.

FIGS. 4A-4E are cross-sectional views of various stages of a process for forming a portion of a semiconductor device structure, in accordance with some embodiments.

FIG. 5 is a cross-sectional view of a stage of a process for forming a portion of a semiconductor device structure, in accordance with some embodiments.

FIG. 6A is a cross-sectional view of a stage of a process for forming a portion of a semiconductor device structure, in accordance with some embodiments.

FIG. 6B is a cross-sectional view of a stage of a process for forming a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using another applicable process.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

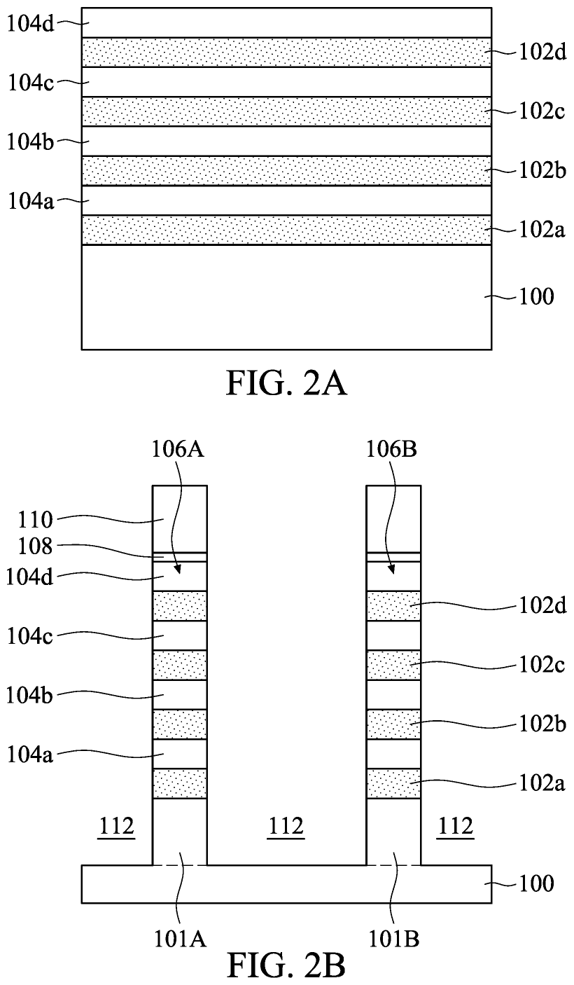

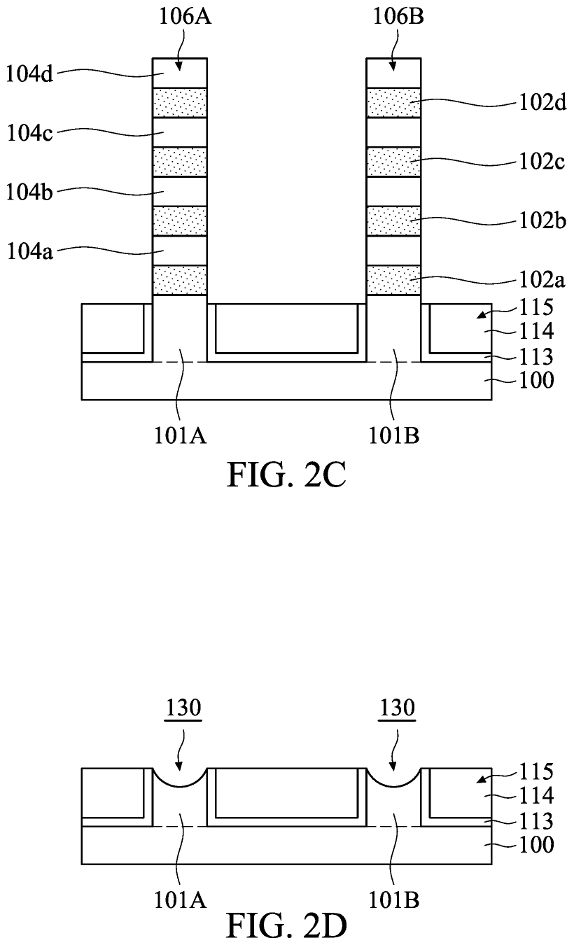

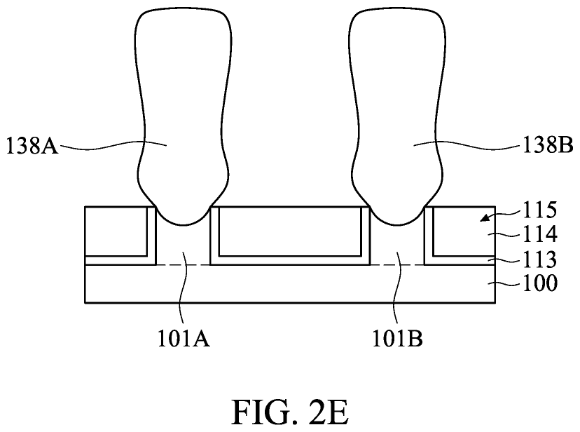

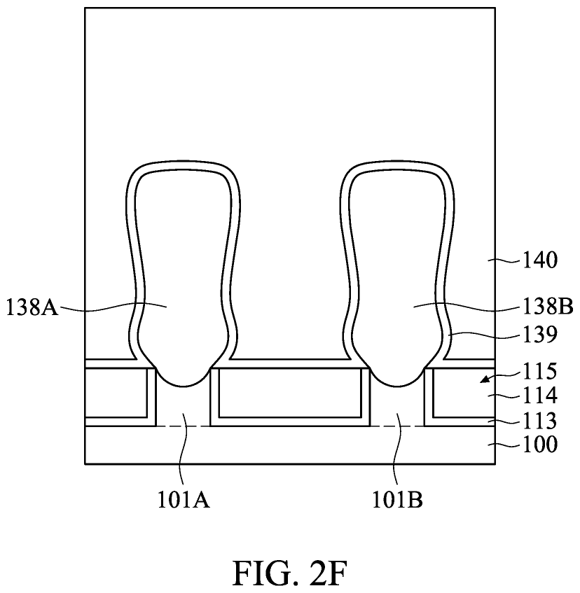

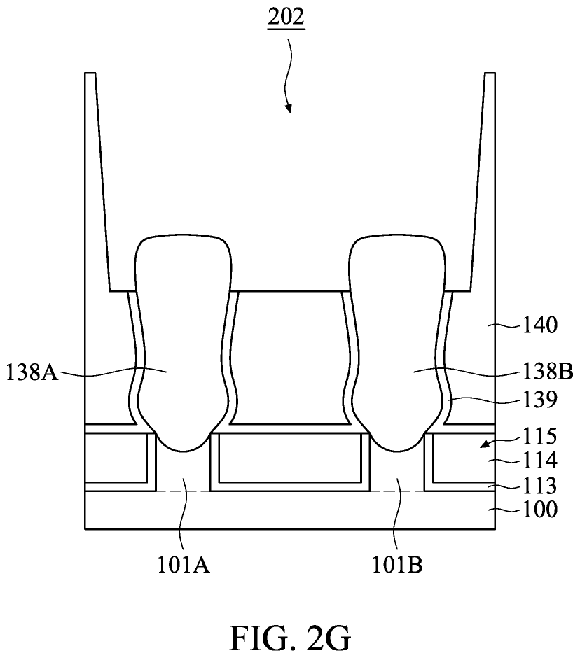

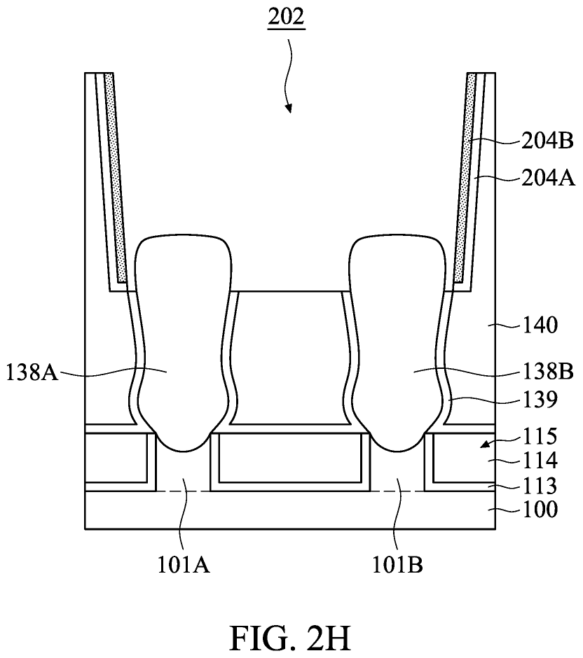

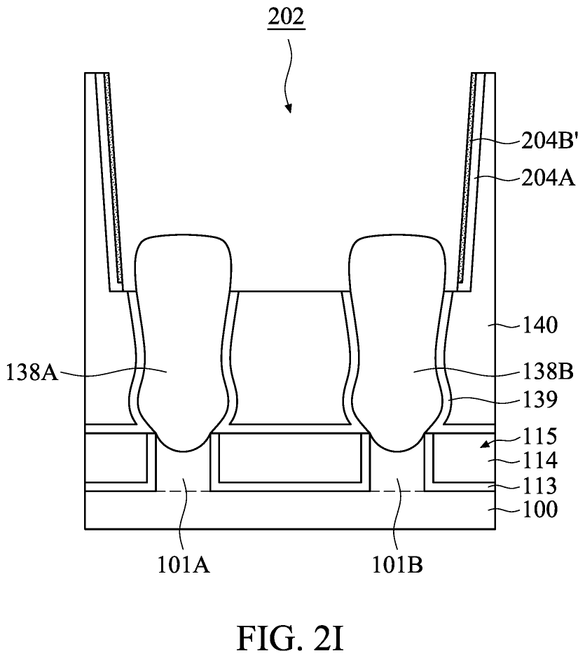

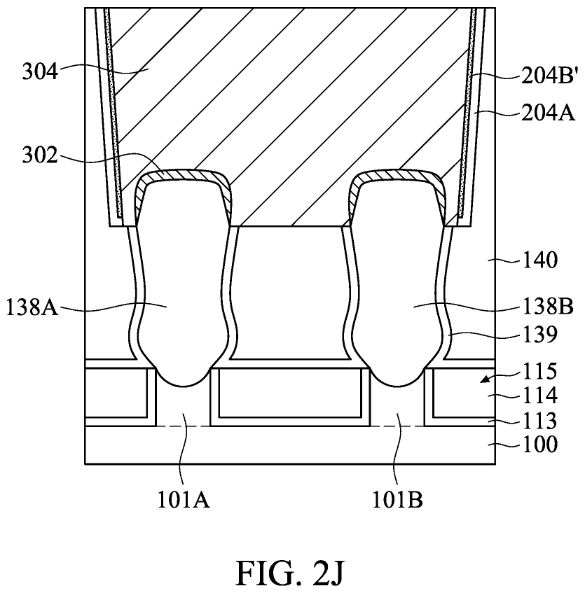

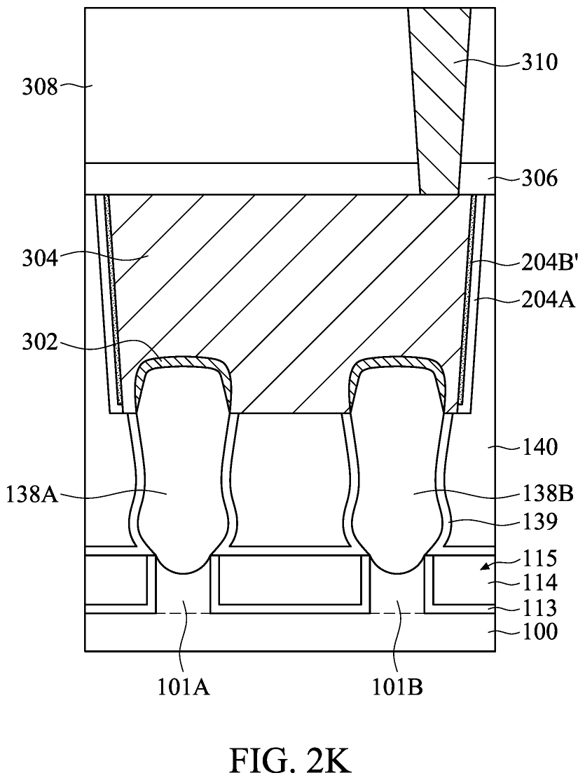

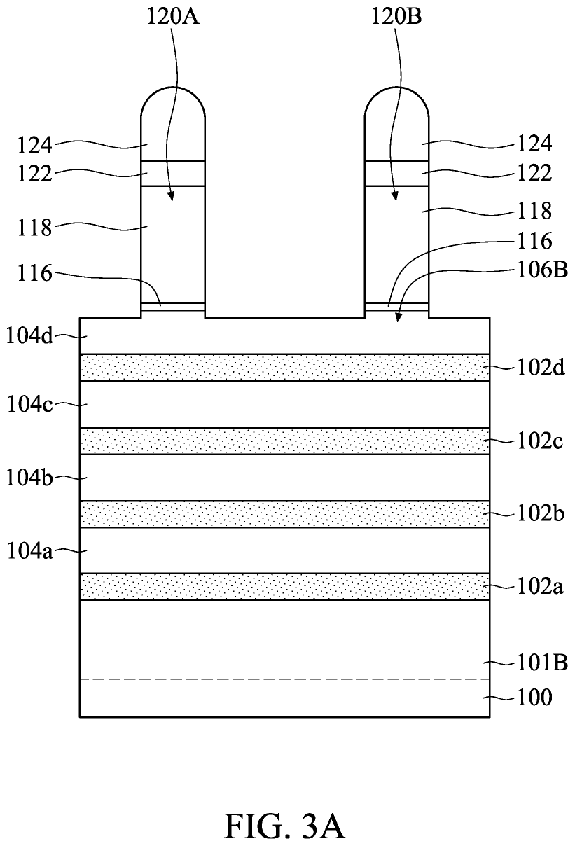

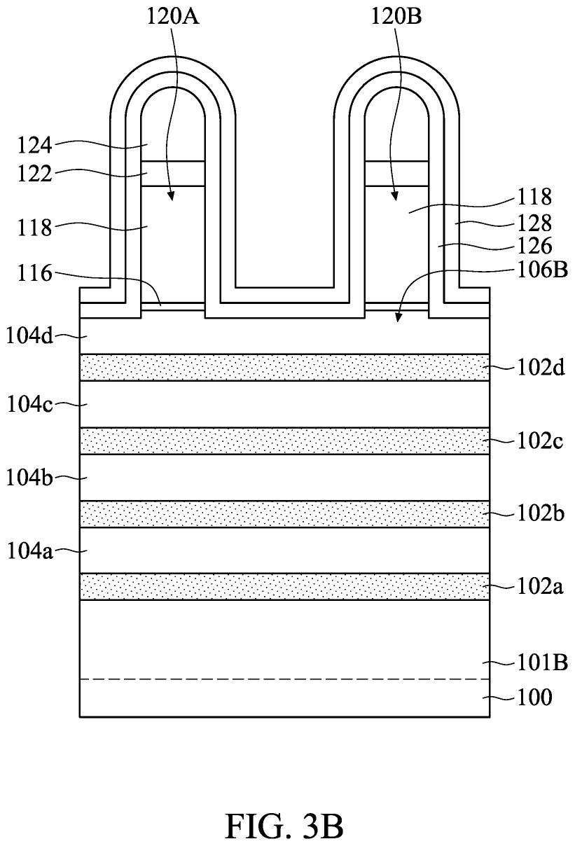

FIGS. 2A-2K are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, another suitable material, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, 102c, and 102d. The semiconductor stack also includes multiple semiconductor layers 104a, 104b, 104c, and 104d. In some embodiments, the semiconductor layers 102a-102d and the semiconductor layers 104a-104d are laid out in an alternating manner, as shown in FIG. 2A. In some embodiments, the semiconductor layers 102a-102d and 104a-104d together form a superlattice structure.

In some embodiments, the semiconductor layers 102a-102d function as sacrificial layers that will be removed in a subsequent process to release the semiconductor layers 104a-104d. The semiconductor layers 104a-104d that are released may function as channel structures of one or more transistors.

In some embodiments, the semiconductor layers 104a-104d that will be used to form channel structures are made of a material that is different than that of the semiconductor layers 102a-102d. In some embodiments, the semiconductor layers 104a-104d are made of or include silicon, germanium, another suitable material, or a combination thereof. In some embodiments, the semiconductor layers 102a-102d are made of or include silicon germanium. In some other embodiments, the semiconductor layers 104a-104d are made of silicon germanium, and the semiconductor layers 102a-102d are made of silicon germanium with different atomic concentration of germanium than that of the semiconductor layers 104a-104d. As a result, different etching selectivity and/or different oxidation rates during subsequent processing may be achieved between the semiconductor layers 102a-102d and the semiconductor layers 104a-104d.

The present disclosure contemplates that the semiconductor layers 102a-102d and the semiconductor layers 104a-104d include any combination of semiconductor materials that can provide desired etching selectivity, desired oxidation rate differences, and/or desired performance characteristics.

In some embodiments, the semiconductor layers 102a-102d and 104a-104d are formed using multiple epitaxial growth operations. Each of the semiconductor layers 102a-102d and 104a-104d may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof.

In some embodiments, the semiconductor layers 102a-102d and 104a-104d are grown in-situ in the same process chamber. In some embodiments, the growth of the semiconductor layers 102a-102d and 104a-104d are alternately and sequentially performed in the same process chamber to complete the formation of the semiconductor stack. In some embodiments, the vacuum of the process chamber is not broken before the epitaxial growth of the semiconductor layers 102a-102d and 104a-104d is accomplished.

Afterwards, hard mask elements are formed over the semiconductor stack to assist in a subsequent patterning of the semiconductor stack. One or more photolithography processes and one or more etching processes are used to pattern the semiconductor stack into multiple fin structures including fin structures 106A and 106B, as shown in FIG. 2B in accordance with some embodiments.

The fin structures 106A and 106B may be patterned by any suitable method. For example, the fin structures 106A and 106B may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

After the patterning of the semiconductor stack, multiple trenches 112 are formed, as shown in FIG. 2B. Each of the fin structures 106A and 106B may include portions of the semiconductor layers 102a-102d and 104a-104d and semiconductor fins 101A and 101B. The semiconductor substrate 100 may also be partially removed during the etching process that forms the fin structures 106A and 106B. Protruding portions of the semiconductor substrate 100 that remain form the semiconductor fins 101A and 101B.

Each of the hard mask elements may include a first mask layer 108 and a second mask layer 110. The first mask layer 108 and the second mask layer 110 may be made of different materials. In some embodiments, the first mask layer 108 is made of a material that has good adhesion to the semiconductor layer 104d. The first mask layer 108 may be made of silicon oxide, germanium oxide, silicon germanium oxide, another suitable material, or a combination thereof. The second layer 110 may be made of silicon nitride, silicon oxynitride, silicon carbide, another suitable material, or a combination thereof. Alternatively, in some other embodiments, the first layer 108 is made of or includes silicon nitride, silicon oxynitride, silicon carbide, another suitable material, or a combination thereof, and the second layer 110 is made of or includes silicon oxide, germanium oxide, silicon germanium oxide, another suitable material, or a combination thereof.

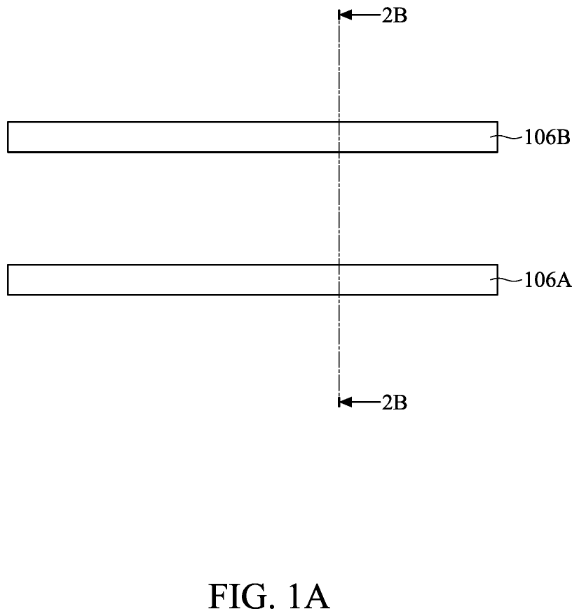

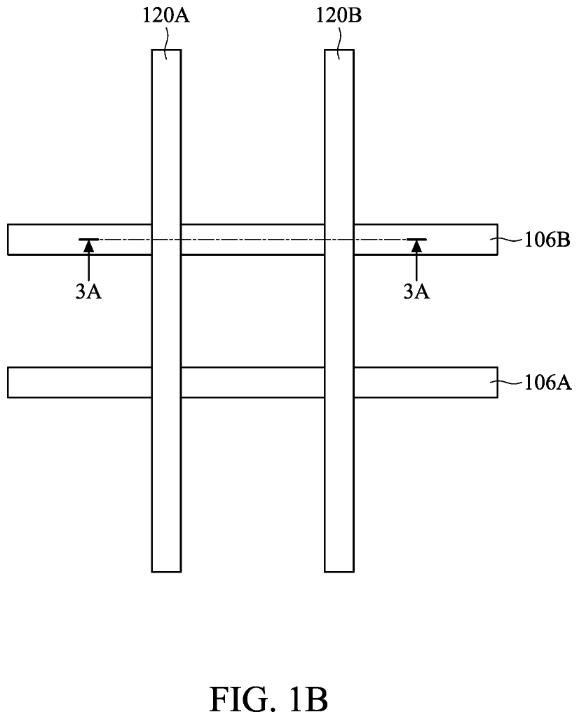

FIGS. 1A-1B are top views of various stages of a process for forming a portion of a semiconductor device structure, in accordance with some embodiments. In some embodiments, the fin structures 106A and 106B are oriented lengthwise. In some embodiments, the longitudinal extending directions of the fin structures 106A and 106B are substantially parallel to each other, as shown in FIG. 1A. In some embodiments, FIG. 2B is a cross-sectional view of the structure taken along the line 2B-2B in FIG. 1A.

As shown in FIG. 2C, an isolation structure 115 is formed to surround lower portions of the fin structures 106A and 106B, in accordance with some embodiments. In some embodiments, the isolation structure 115 includes a dielectric filling 114 and a liner layer 113 that is adjacent to the semiconductor fins 101A and 101B and the semiconductor substrate 100. In some embodiments, the semiconductor fins 101A and 101B protrude from the top surface of the isolation structure 115.

In some embodiments, the liner layer 113 and one or more dielectric layers are deposited over the fin structures 106A and 106B and the semiconductor substrate 100 to overfill the trenches 112. The liner layer 113 may be made of or include silicon nitride, silicon oxynitride, silicon carbide, silicon oxycarbide, another suitable material, or a combination thereof. The dielectric layers may be made of silicon oxide, silicon oxynitride, borosilicate phosphoric glass (BSG), silicate glass (PSG), borophosphosilicate glass (BPSG), fluorinated silicate glass (FSG), low-k material, porous dielectric material, another suitable material, or a combination thereof. The liner layer 113 and the dielectric layers may be sequentially deposited using a flowable chemical vapor deposition (FCVD) process, an atomic layer deposition (ALD) process, a chemical vapor deposition (CVD) process, another applicable process, or a combination thereof.

Afterwards, a planarization process is used to partially remove the dielectric layers and the liner layer 113. The hard mask elements (including the first mask layer 108 and the second mask layer 110) may also function as stop layers of the planarization process. The planarization process may include a chemical mechanical polishing (CMP) process, a grinding process, a dry polishing process, an etching process, another applicable process, or a combination thereof.

Afterwards, one or more etching back processes are used to partially remove the dielectric layers and the liner layer 113. As a result, the remaining portion of the dielectric layers forms the dielectric filling 114 of the isolation structure 115. Upper portions of the fin structures 106A and 106B protrude from the top surface of the isolation structure 115, as shown in FIG. 2C.

In some embodiments, the etching back process for forming the isolation structure 115 is carefully controlled to ensure that the topmost surface of the isolation structure 115 is positioned at a suitable height level. In some embodiments, the topmost surface of the isolation structure 115 is below the bottommost surface of the semiconductor layer 102a which functions as a sacrificial layer, as shown in FIG. 2C.

Afterwards, the remaining portions of the hard mask elements (including the first mask layer 108 and the second mask layer 110) are removed. Alternatively, in some other embodiments, the hard mask elements are removed or consumed during the planarization process and/or the etching back process that forms the isolation structure 115.

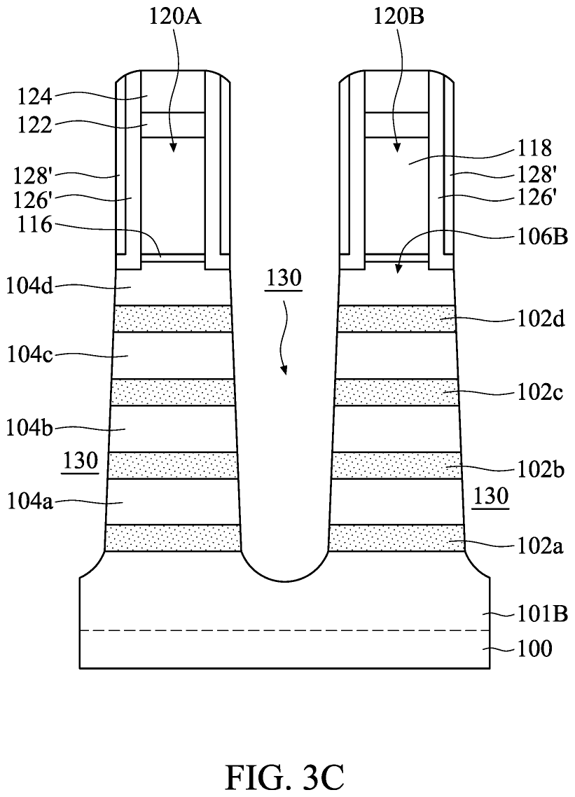

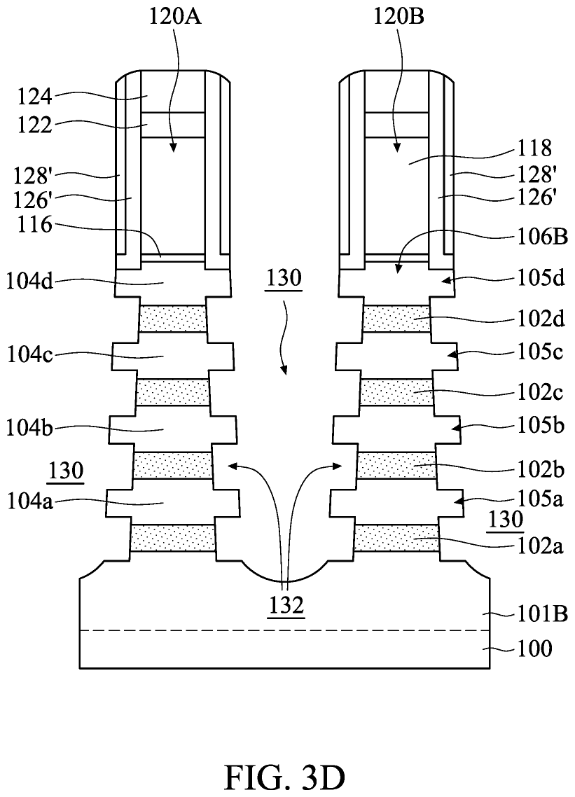

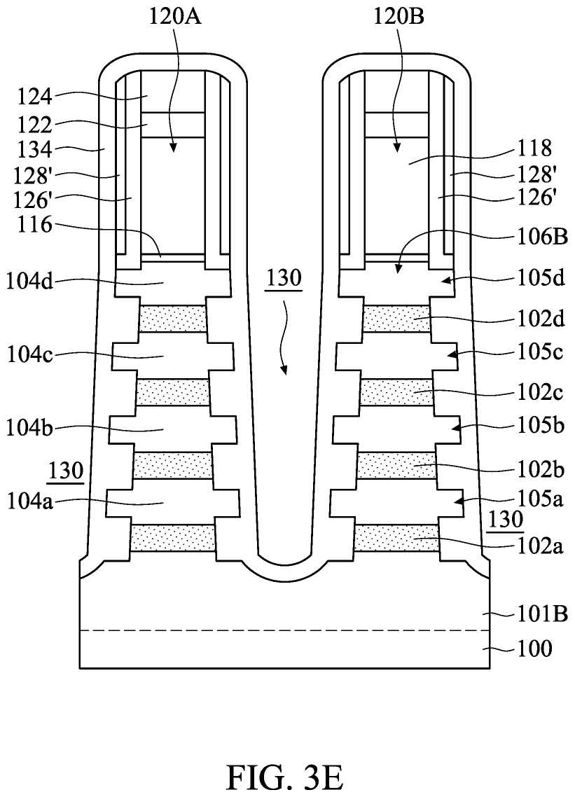

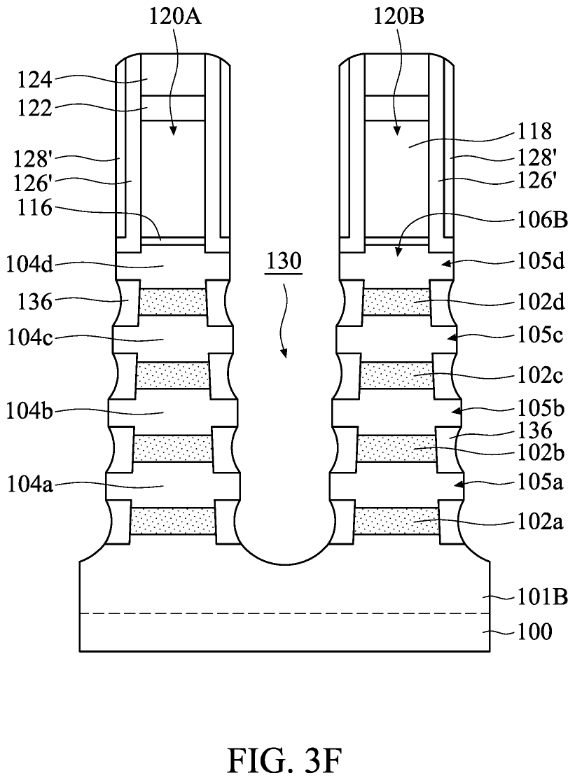

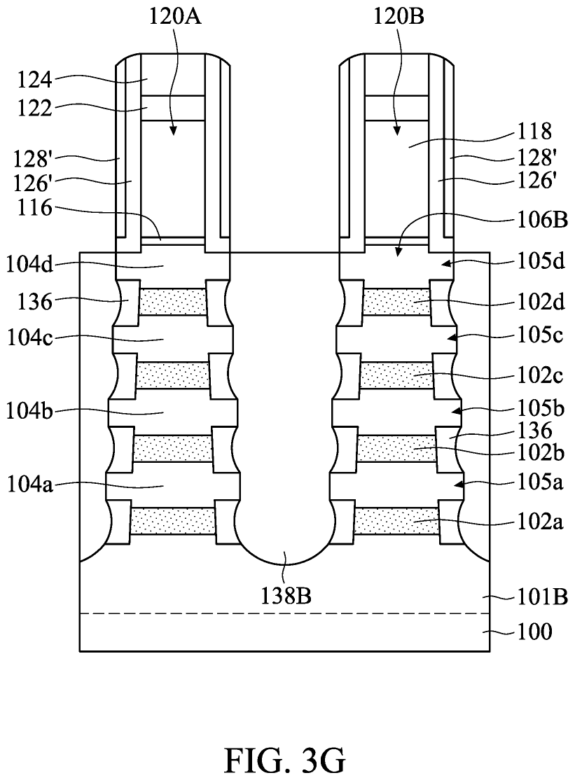

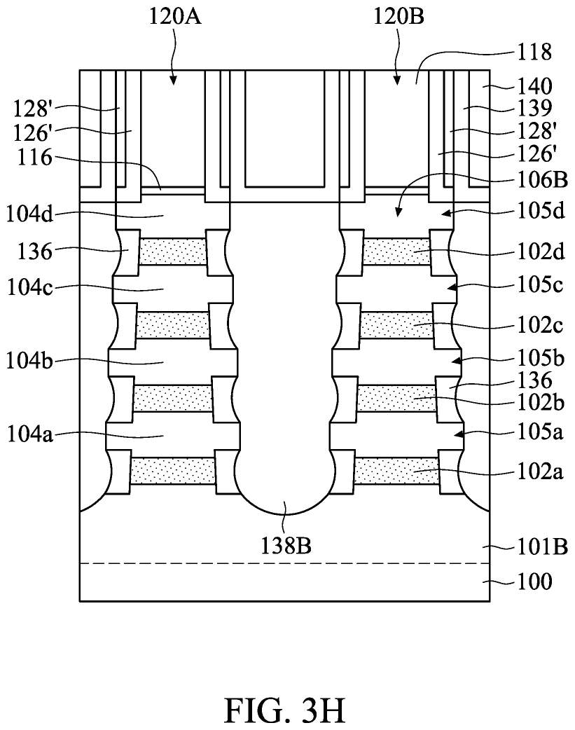

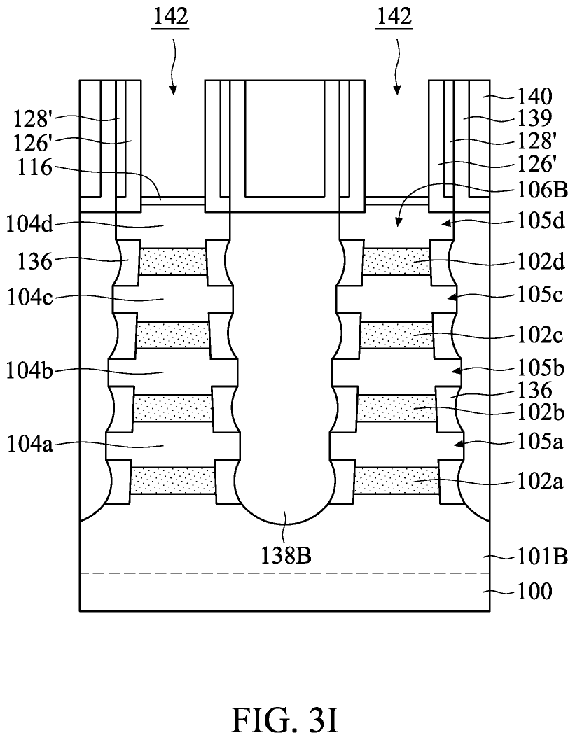

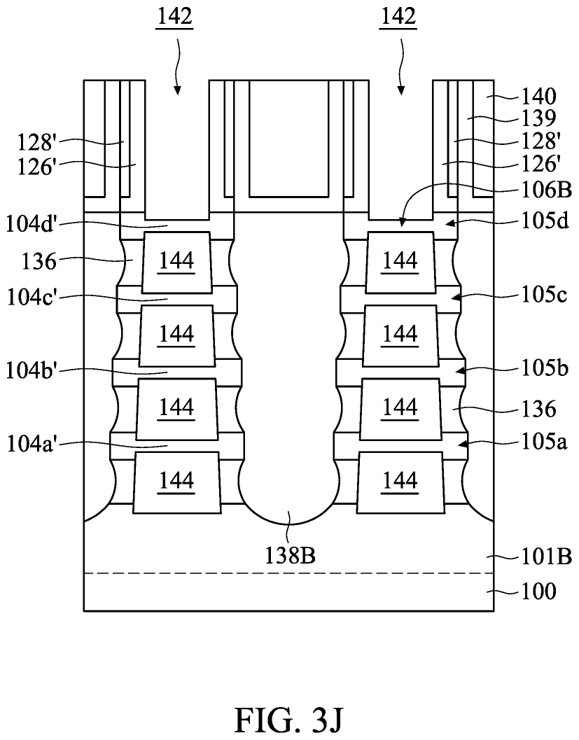

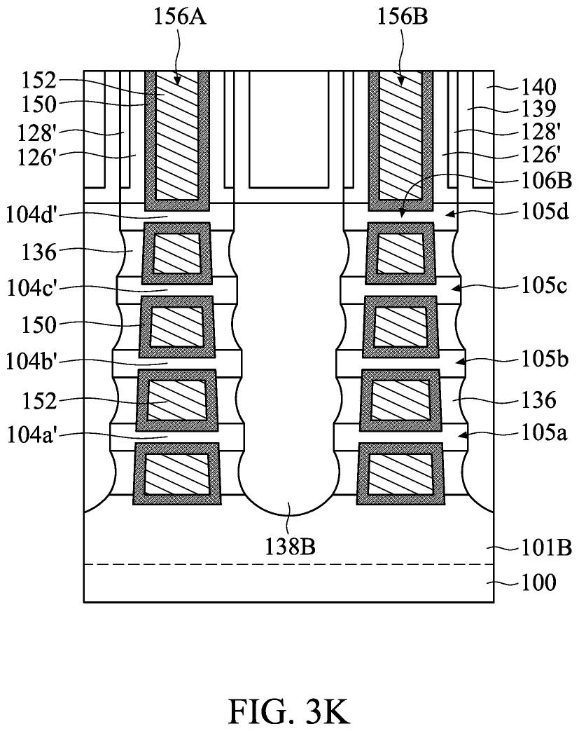

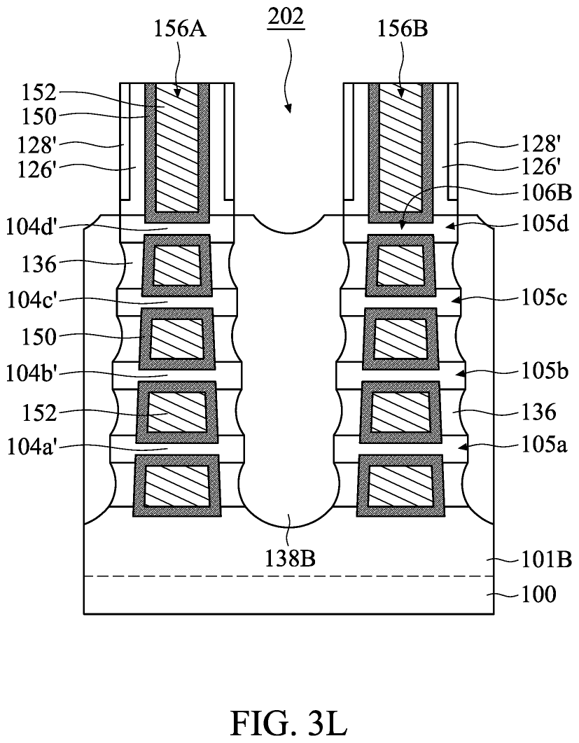

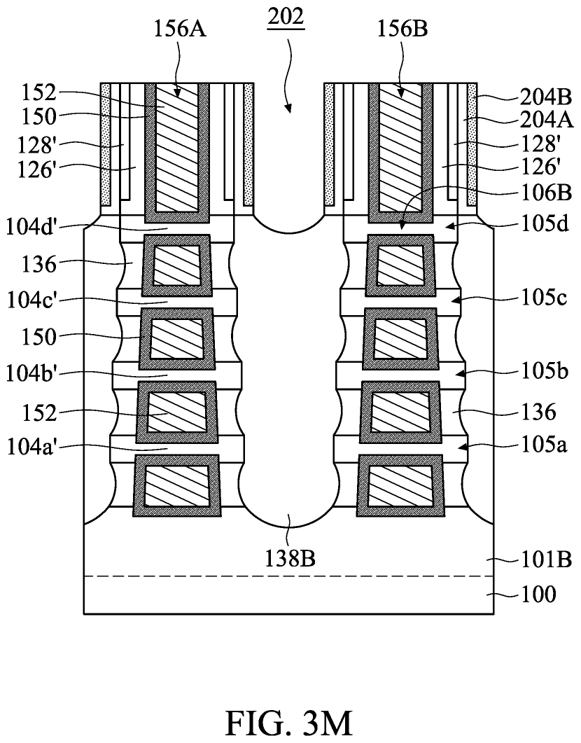

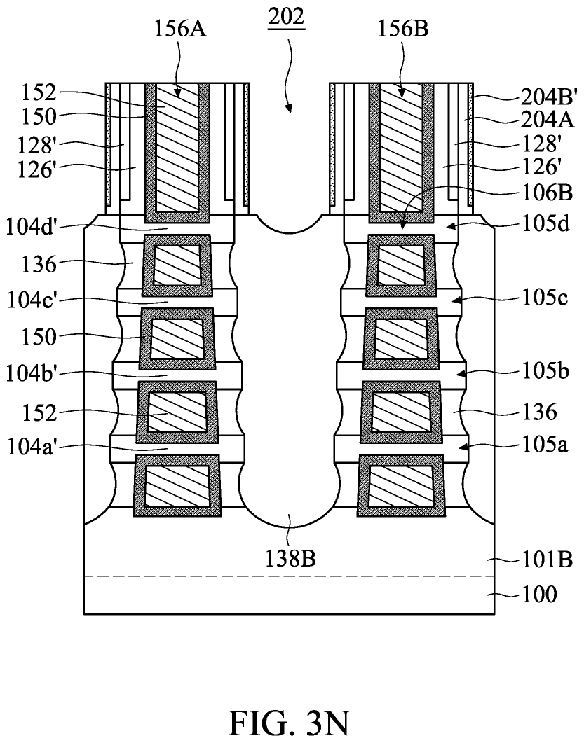

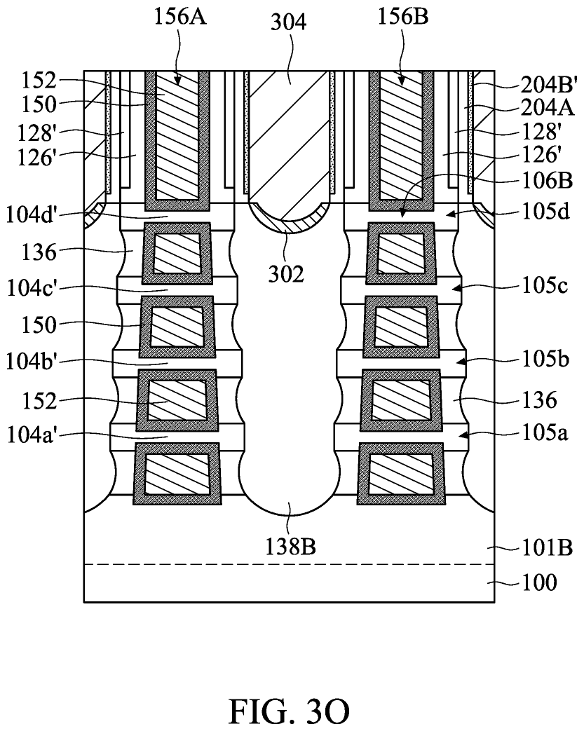

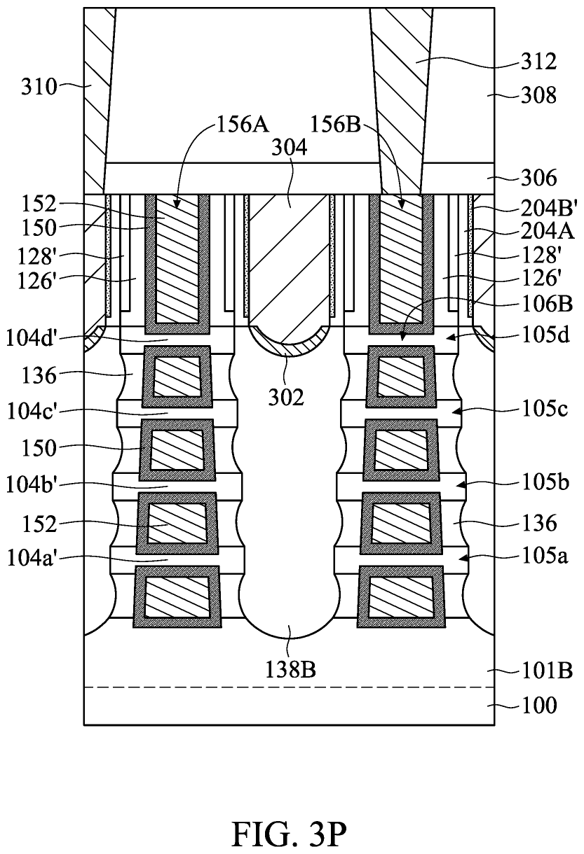

Afterwards, dummy gate stacks 120A and 120B are formed to extend across the fin structures 106A and 106B, as shown in FIG. 1B in accordance with some embodiments. FIGS. 3A-3P are cross-sectional views of various stages of a process for forming a portion of a semiconductor device structure, in accordance with some embodiments. In some embodiments, FIG. 3A is a cross-sectional view of the structure taken along the line 3A-3A in FIG. 1B.

As shown in FIGS. 1B and 3A, the dummy gate stacks 120A and 120B are formed to partially cover and to extend across the fin structures 106A and 106B, in accordance with some embodiments. In some embodiments, the dummy gate stacks 120A and 120B are wrapped around portions of the fin structures 106A and 106B. As shown in FIG. 1B, other portions of the fin structures 106A and 106B are exposed without being covered by the dummy gate stacks 120A and 120B.

As shown in FIG. 3A, each of the dummy gate stacks 120A and 120B includes a dummy gate dielectric layer 116 and a dummy gate electrode 118. The dummy gate dielectric layers 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106A and 106B. The dummy gate dielectric material layer may be deposited using an ALD process, a CVD process, another applicable process, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements including mask layers 122 and 124 are used to assist in the patterning process for forming the dummy gate stacks 120A and 120B. With the hard mask elements as an etching mask, one or more etching processes are used to partially remove the dummy gate dielectric material layer and the dummy gate electrode layer. As a result, remaining portions of the dummy gate dielectric material layer and the dummy gate electrode layer respectively form the dummy gate dielectric layers 116 and the dummy gate electrodes 118 of the dummy gate stacks 120A and 120B.

As shown in FIG. 3B, spacer layers 126 and 128 are afterwards deposited over the dummy gate stacks 120A and 120B and the fin structure 106B, in accordance with some embodiments. The spacer layers 126 and 128 extend along the tops and sidewalls of the dummy gate stacks 120A and 120B, as shown in FIG. 3B. The spacer layers 126 and 128 also extend along the top of the fin structure 106B, as shown in FIG. 3B.

The spacer layers 126 and 128 are made of different materials. The spacer layer 126 may be made of a dielectric material that had better etchant resistance. The spacer layer 126 may have a higher dielectric constant than that of the spacer layer 128. The spacer layer 126 may be made of silicon nitride, silicon oxynitride, carbon-containing silicon nitride, carbon-containing silicon oxynitride, another suitable material, or a combination thereof. The spacer layer 128 may be made of a dielectric material that has a low dielectric constant. The spacer layer 128 may be made of or include silicon carbide, silicon oxycarbide, carbon-containing silicon oxynitride, silicon oxide, another suitable material, or a combination thereof. In some embodiments, the spacer layer 128 is a single layer. In some other embodiments, the spacer layer 128 includes multiple sub-layers. Some of the sub-layers may be made of different materials. Some of the sub-layers may be made of similar materials with different compositions. For example, one of the sub-layers may have a greater atomic concentration of carbon than other sub-layers. In some other embodiments, the spacer layer 128 is deposited before the spacer layer 126. The positions of the spacer layers 126 and 128 may be switched. The spacer layers 126 and 128 may be sequentially deposited using a CVD process, an ALD process, a physical vapor deposition (PVD) process, another applicable process, or a combination thereof.

However, embodiments of the disclosure are not limited thereto. Many variations and/or modifications can be made to embodiments of the disclosure. In some other embodiments, the spacer layer 128 has a lower dielectric constant than that of the spacer layer 126.

As shown in FIG. 3C, the spacer layers 126 and 128 are partially removed, in accordance with some embodiments. One or more anisotropic etching processes may be used to partially remove the spacer layers 126 and 128. As a result, remaining portions of the spacer layers 126 and 128 form gate spacers 126′ and 128′, respectively. The gate spacers 126′ and 128′ extend along the sidewalls of the dummy gate stacks 120A and 120B, as shown in FIG. 3C.

The fin structures 106A and 106B are partially removed to form recesses used for containing subsequently formed epitaxial structures. As shown in FIGS. 2D and 3C, the fin structures 106A and 106B are partially removed to form recesses 130, in accordance with some embodiments. As shown in FIG. 3C, the recesses 130 expose the side surfaces of the semiconductor layers 104a-104d on which epitaxial structures (such as source/drain structures) will be formed later. Source/drain structures may refer to a source structure or a drain structure, individually or collectively dependent upon the context.

One or more etching processes may be used to form the recesses 130. In some embodiments, a dry etching process is used to form the recesses 130. Alternatively, a wet etching process may be used to form the recesses 130. In some embodiments, each of the recesses 130 penetrates into the fin structure 106A or 106B. In some embodiments, the recesses 130 further extend into the semiconductor fins 101A and 101B, as shown in FIGS. 2D and 3C. In some embodiments, the gate spacers 126′ and 128′ and the recesses 130 are simultaneously formed using the same etching process within the same process chamber.

In some embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

However, embodiments of the disclosure have many variations. In some other embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

As shown in FIG. 3D, the semiconductor layers 102a-102d are laterally etched, in accordance with some embodiments. As a result, edges of the semiconductor layers 102a-102d retreat from edges of the semiconductor layers 104a-104d. As shown in FIG. 3D, recesses 132 are formed due to the lateral etching of the semiconductor layers 102a-102d. The recesses 132 may be used to contain inner spacers that will be formed later. The semiconductor layers 102a-102d may be laterally etched using a wet etching process, a dry etching process, or a combination thereof. In some other embodiments, the semiconductor layers 102a-102d are partially oxidized before being laterally etched.

During the lateral etching of the semiconductor layers 102a-102d, the semiconductor layers 104a-104d may also be slightly etched. As a result, edge portions of the semiconductor layers 104a-104d are partially etched and thus shrink to form edge elements 105a-105d, as shown in FIG. 3D. Each of the edge elements 105a-105d of the semiconductor layers 104a-104d is thinner than the corresponding inner portion of the semiconductor layers 104a-104d.

As shown in FIG. 3E, an insulating layer 134 is deposited over the structure shown in FIG. 3D, in accordance with some embodiments. The insulating layer 134 covers the dummy gate stacks 120A and 120B and overfills the recesses 132. The insulating layer 134 may be made of or include carbon-containing silicon nitride (SiCN), carbon-containing silicon oxynitride (SiOCN), carbon-containing silicon oxide (SiOC), silicon oxide, silicon nitride, another suitable material, or a combination thereof. In some embodiments, the insulating layer 134 is a single layer. In some other embodiments, the insulating layer 134 includes multiple sub-layers. Some of the sub-layers may be made of different materials and/or contain different compositions. The insulating layer 134 may be deposited using a CVD process, an ALD process, another applicable process, or a combination thereof.

As shown in FIG. 3F, an etching process is used to partially remove the insulating layer 134, in accordance with some embodiments. The portions of the insulating layer 134 outside of the recesses 132 may be removed. The remaining portions of the insulating layer 134 form multiple inner spacers 136, as shown in FIG. 3F. The etching process may include a dry etching process, a wet etching process, or a combination thereof.

The inner spacers 136 cover the edges of the semiconductor layers 102a-102d. The inner spacers 136 may be used to prevent subsequently formed epitaxial structures (which function as source/drain structures, for example) from being damaged during a subsequent process for removing the semiconductor layers 102a-102d. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136, portions of the semiconductor fin 101B originally covered by the insulating layer 134 are exposed by the recesses 130, as shown in FIG. 3F. The edges of the semiconductor layers 104a-104d are also exposed by the recesses 130, as shown in FIG. 3F.

As shown in FIGS. 2E and 3G, epitaxial structures 138A and 138B are sequentially and respectively formed on the semiconductor fins 101A and 101B and the side surfaces of the semiconductor layers 104a-104d, in accordance with some embodiments. Patterned mask elements may be formed to assist in the selective formation of the epitaxial structures 138A and 138B on the respective positions.

In some embodiments, the epitaxial structures 138B connect to the semiconductor layers 104a-104d, as shown in FIG. 3G. Each of the semiconductor layers 104a-104d is sandwiched between two of the epitaxial structures 138B. In some embodiments, the epitaxial structures 138B have lightly doped portions adjacent to the semiconductor layers 104a-104d. The dopant concentration of the lightly doped portions is lower than other portions of the epitaxial structures 138.

In some embodiments, the epitaxial structures 138B are p-type doped regions. The epitaxial structures 138B may include epitaxially grown silicon germanium (SiGe), epitaxially grown silicon, or another suitable epitaxially grown semiconductor material. P-type dopants may include boron, another suitable element, or a combination thereof.

However, embodiments of the disclosure are not limited thereto. In some other embodiments, the epitaxial structures 138B are n-type doped regions. The epitaxial structures 138B may include epitaxially grown silicon, epitaxially grown silicon carbide (SiC), epitaxially grown germanium, or another suitable epitaxially grown semiconductor material. N-type dopants may include phosphor, arsenic, another suitable element, or a combination thereof.

In some embodiments, the epitaxial structures 138B are doped in-situ during their epitaxial growth. The initial reaction gas mixture for forming the epitaxial structures 138B contains dopants. In some other embodiments, the epitaxial structures 138B are not doped during the growth of the epitaxial structures 138B. Instead, after the formation of the epitaxial structures 138B, the epitaxial structures 138B are doped in a subsequent process. In some embodiments, the doping is achieved by using an ion implantation process, a plasma immersion ion implantation process, a gas and/or solid source diffusion process, another applicable process, or a combination thereof. In some embodiments, the epitaxial structures 138B are further exposed to one or more annealing processes to activate the dopants. For example, a rapid thermal annealing process is used.

In some embodiments, the epitaxial structures 138A and 138B shown in FIG. 2E have different conductivity types. In some embodiments, the epitaxial structure 138A is n-type doped, and the epitaxial structure 138B is p-type doped. In some other embodiments, the epitaxial structure 138A is p-type doped, and the epitaxial structure 138B is n-type doped. In some embodiments, the epitaxial structures 138A and 138B are formed separately. In some embodiments, the epitaxial structure 138A is formed before the epitaxial structure 138B. In some other embodiments, the epitaxial structure 138A is formed after the epitaxial structure 138B.

As shown in FIGS. 2F and 3H, a contact etch stop layer 139 and a dielectric layer 140 are formed over the structure shown in FIGS. 2E and 3G to laterally surround the epitaxial structures 138A and 138B and the dummy gate stacks 120A and 120B, in accordance with some embodiments. The contact etch stop layer 139 may be made of or include silicon nitride, silicon oxynitride, silicon carbide, carbon-containing silicon nitride, carbon-containing silicon oxynitride, carbon-containing silicon oxide, aluminum oxide, another suitable material, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited. The etch stop material layer may be deposited using a CVD process, an ALD process, a PVD process, another applicable process, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIGS. 2F and 3H. The planarization process may include a CMP process, a grinding process, an etching process, a dry polishing process, another applicable process, or a combination thereof. In some embodiments, the mask layers 122 and 124 over the dummy gate stacks 120A and 120B are removed during the planarization process. In some embodiments, after the planarization process, the top surfaces of the contact etch stop layer 139, the dielectric layer 140, and the dummy gate electrodes 118 are substantially level with each other.

Afterwards, a gate replacement process is performed to replace the dummy gate stacks 120A and 120B with metal gate stacks, in accordance with some embodiments. In some embodiments, the dummy gate electrodes 118 are removed to form trenches 142 using one or more etching processes, as shown in FIG. 31. The trenches 142 expose the dummy gate dielectric layer 116.

Afterwards, the dummy gate dielectric layer 116 and the semiconductor layers 102a-102d (which function as sacrificial layers) are removed, as shown in FIG. 3J in accordance with some embodiments. In some embodiments, one or more etching processes are used to remove the dummy gate dielectric layer 116 and the semiconductor layers 102a-102d. As a result, recesses 144 are formed between the inner spacers 136, as shown in FIG. 3J.

Due to high etching selectivity, the semiconductor layers 104a-104d are slightly (or substantially not) etched. The remaining portions of the semiconductor layers 104a-104d form multiple semiconductor nanostructures 104a′-104d′. The semiconductor nanostructures 104a′-104d′ are constructed by or made up of the remaining portions of the semiconductor layers 104a-104d. The semiconductor nanostructures 104a′-104d′ may function as channel structures of transistors.

In some embodiments, the etchant used for removing the semiconductor layers 102a-102d also slightly removes the semiconductor layers 104a-104d that form the semiconductor nanostructures 104a′-104d′. As a result, the obtained semiconductor nanostructures 104a′-104d′ become thinner after the removal of the semiconductor layers 102a-102d. In some embodiments, each of the semiconductor nanostructures 104a′-104d′ is thinner than each of the edge elements 105a-105d since the edge elements 105a-105d are surrounded by other elements and thus are prevented from being reached and etched by the etchant. In some other embodiments, each of the semiconductor nanostructures 104a′-104d′ is substantially as thick as each of the edge elements 105a-105d.

After the removal of the semiconductor layers 102a-102d (which function as sacrificial layers), the recesses 144 are formed. The recesses 144 surround each of the semiconductor nanostructures 104a′-104d′. Even if the recesses 144 between the semiconductor nanostructures 104a′-104d′ are formed, the semiconductor nanostructures 104a′-104d′ remain held by the epitaxial structures 138B. Therefore, after the removal of the semiconductor layers 102a-102d (which function as sacrificial layers), the released semiconductor nanostructures 104a′-104d′ are prevented from falling.

During the removal of the semiconductor layers 102a-102d (which function as sacrificial layers), the inner spacers 136 protect the epitaxial structures 138A and 138B from being etched or damaged. The quality and reliability of the semiconductor device structure are improved.

As shown in FIG. 3K, metal gate stacks 156A and 156B are formed to fill the trenches 142, in accordance with some embodiments. The metal gate stacks 156A and 156B further extend into the recesses 144 to wrap around each of the semiconductor nanostructures 104a′-104d′. As a result, the dummy gate stacks 120A and 120B are replaced with the metal gate stacks 156A and 156B, respectively.

Each of the metal gate stacks 156A and 156B includes multiple metal gate stack layers. Each of the metal gate stacks 156A and 156B may include a gate dielectric layer 150 and a metal gate electrode 152. The metal gate electrode 152 may include one or more work function layers. The metal gate electrode 152 may further include a conductive filling. In some embodiments, the formation of the metal gate stacks 156A and 156B involves the deposition of multiple metal gate stack layers over the dielectric layer 140 to fill the trenches 142 and the recesses 144. The metal gate stack layers extend into the recesses 144 to wrap around each of the semiconductor nanostructures 104a′-104d′.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, another applicable process, or a combination thereof.

In some embodiments, before the formation of the gate dielectric layer 150, interfacial layers are formed on the surfaces of the semiconductor nanostructures 104a′-104d′. The interfacial layers are very thin and are made of, for example, silicon oxide and/or germanium oxide. In some embodiments, the interfacial layers are formed by applying an oxidizing agent on the surfaces of the semiconductor nanostructures 104a′-104d′. For example, a hydrogen peroxide-containing liquid may be applied or introduced on the surfaces of the semiconductor nanostructures 104a′-104d′ so as to form the interfacial layers.

The work function layer of the metal gate electrode 152 may be used to provide the desired work function for transistors to enhance device performance including improved threshold voltage. In some embodiments, the work function layer is used for forming a PMOS device. The work function layer is a p-type work function layer. The p-type work function layer is capable of providing a work function value that is suitable for the device, such as about 4.8 eV or higher.

The p-type work function layer may include metal, metal carbide, metal nitride, another suitable material, or a combination thereof. For example, the p-type metal includes tantalum nitride, tungsten nitride, titanium, titanium nitride, another suitable material, or a combination thereof.

In some other embodiments, the work function layer is used for forming an NMOS device. The work function layer is an n-type work function layer. The n-type work function layer is capable of providing a work function value that is suitable for the device, such as about 4.5 eV or less.

The n-type work function layer may include metal, metal carbide, metal nitride, or a combination thereof. For example, the n-type work function layer includes titanium nitride, tantalum, tantalum nitride, another suitable material, or a combination thereof. In some embodiments, the n-type work function is an aluminum-containing layer. The aluminum-containing layer may be made of or include TiAlC, TiAlO, TiAlN, another suitable material, or a combination thereof.

The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 150 using an ALD process, a CVD process, a PVD process, an electroplating process, an electrochemical plating process, another applicable process, or a combination thereof.

In some embodiments, a barrier layer is formed before the work function layer to interface the gate dielectric layer 150 with the subsequently formed work function layer. The barrier layer may also be used to prevent diffusion between the gate dielectric layer 150 and the subsequently formed work function layer. The barrier layer may be made of or include a metal-containing material. The metal-containing material may include titanium nitride, tantalum nitride, another suitable material, or a combination thereof. The barrier layer may be deposited using an ALD process, a CVD process, a PVD process, an electroplating process, an electrochemical plating process, another applicable process, or a combination thereof.

In some embodiments, different portions of the metal gate stacks 156A and 156B are wrapped around the semiconductor nanostructures 104a′-104d′ of PMOS devices and the semiconductor nanostructures 104a′-104d′ of NMOS devices. Different portions of the metal gate stacks 156A and 156B thus have different types of work function layer or different combinations of work functions layers. Multiple deposition processes and multiple patterning processes may be used to selectively form different work function layers at different portions of the metal gate stacks 156A and 156B.

In some embodiments, the conductive fillings of the metal gate electrodes 152 are made of or include a metal material. The metal material may include tungsten, ruthenium, aluminum, copper, cobalt, another suitable material, or a combination thereof. A conductive layer used for forming the conductive filling may be deposited over the work function layer using a CVD process, an ALD process, a PVD process, an electroplating process, an electrochemical plating process, a spin coating process, another applicable process, or a combination thereof.

In some embodiments, a blocking layer is formed over the work function layer before the formation of the conductive layer used for forming the conductive filling. The blocking layer may be used to prevent the subsequently formed conductive layer from diffusing or penetrating into the work function layer. The blocking layer may be made of or include tantalum nitride, titanium nitride, another suitable material, or a combination thereof. The blocking layer may be deposited using an ALD process, a PVD process, an electroplating process, an electrochemical plating process, another applicable process, or a combination thereof.

Afterwards, a planarization process is performed to remove the portions of the metal gate stack layers outside of the trenches 142, in accordance with some embodiments. As a result, the remaining portions of the metal gate stack layers form the metal gate stacks 156A and 156B, as shown in FIG. 3K.

As shown in FIGS. 2G and 3L, the dielectric layer 140 and the contact etch stop layer 139 are partially removed, in accordance with some embodiments. As a result, multiple contact openings 202 are formed. One or more photolithography processes and one or more etching processes may be used to form the contact openings 202. In some embodiments, the epitaxial structures 138A and 138B are recessed due to the etching process for forming the contact openings 202.

As shown in FIGS. 2H and 3M, protective layers 204A and 204B are sequentially formed over sidewalls of the contact openings 202, in accordance with some embodiments. The protective layers 204A and 204B may together form a protective structure. The protective structure may be used to protective the dielectric layer 140 during the subsequent processes. In some embodiments, the inner portion of the protective structure (i.e., the protective layer 204A) is in direct contact with the gate spacers 128′ and 126′ and the dielectric layer 140.

In some embodiments, the protective layer 204A has a lower dielectric constant than that of the protective layer 204B. In some embodiments, the protective layer 204A is made of or include a low-k dielectric material, and the protective layer 204B is made of a material that has better resistance to cleaning agent and/or etchant than the protective layer 204A. The protective layer 204A may be made of or includes carbon-containing silicon oxide, silicon carbide, silicon oxide, carbon-containing silicon oxynitride, carbon-containing silicon nitride, another suitable material, or a combination thereof. The protective layer 204B may be made of or include silicon nitride, silicon oxynitride, carbon-containing silicon nitride, carbon-containing silicon oxynitride, another suitable material, or a combination thereof.

In some embodiments, the protective layer 204B has a higher atomic concentration of nitrogen than that of the protective layer 204A. In some embodiments, the protective layer 204A is substantially free of nitrogen. In some embodiments, the protective layer 204A has a higher atomic concentration of oxygen than that of the protective layer 204B. In some embodiments, the protective layer 204B is substantially free of oxygen. The subsequent formed conductive contact may thus be prevented from being oxidized due to the protective layer 204B. The performance and reliability of the semiconductor device structure may be improved.

In some embodiments, a first protective material layer and a second protective material layer are sequentially deposited over the sidewalls and bottoms of the contact openings 202. The first protective material layer and the second protective material layer may be deposited using a CVD process, an ALD process, another applicable process, or a combination thereof. Afterwards, an anisotropic etching process is used to remove the portions of the first protective material layer and the second protective material layer at the bottoms of the contact openings 202. As a result, the remaining portions of the first protective material layer and the second protective material layer form the protective layers 204A and 204B, respectively.

Afterwards, before a subsequent formation of metal-semiconductor compound features, a cleaning operation is performed to clean the exposed surfaces of the epitaxial structures 138A and 138B, as shown in FIGS. 2I and 3N in accordance with some embodiments. During the cleaning operation, the protective layer 204B may prevent the dielectric layer 140 from being damaged by the cleaning operation. The position and

profile of the contact openings 202 may thus be maintained, which facilitate the subsequent formation of conductive contacts in the contact openings 202.

In some embodiments, the protective layer 204B is partially consumed during the cleaning operation. As a result, a protective layer 204B′, that becomes thinner than the originally formed protective layer 204B, is formed, as shown in FIGS. 2I and 3N. In some other embodiments, the protective layer 204B is completely consumed.

As shown in FIGS. 2J and 3O, metal-semiconductor compound features 302 are formed on the surfaces of the epitaxial structures 138A and 138B that are exposed by the contact openings 202, in accordance with some embodiments. In some embodiments, before the formation of the metal-semiconductor compound features 302, the exposed epitaxial structures 138A and 138B are modified to assist in the subsequent formation of the metal-semiconductor compound features 302. In some embodiments, one or more ion implantation processes are used to reduce the crystallinity of the surface portions of the epitaxial structures 138A and 138B, which allows a subsequently deposited metal material to react with the modified surface portions more easily. The formation of the metal-semiconductor compound features 302 may thus be facilitated.

In some embodiments, the implantation process is a plasma doping process. Plasma may be introduced into the contact openings 202 to modify the exposed surface portions of the epitaxial structures 138A and 138B. In some embodiments, reaction gas used in the implantation process includes silicon-containing gas, germanium-containing gas, argon-containing gas, helium-containing gas, another suitable gas, or a combination thereof.

In some embodiments, a thermal operation is performed after a metal-containing material is applied (or deposited) on the epitaxial structures 138A and 138B. In some other embodiments, a metal-containing material is applied (or deposited) on the epitaxial structures 138A and 138B while the epitaxial structures 138A and 138B are heated, in accordance with some embodiments. In some embodiments, the metal-containing material is applied (or deposited) using a CVD process, an ALD process, or a combination thereof.

Due to the thermal operation, the thermal energy may help to initiate chemical reaction between the surface portions of the epitaxial structures 138A and 138B and the metal-containing material. As a result, the surface portions of the epitaxial structures 138A and 138B react with the metal-containing material, and they are transformed into the metal-semiconductor compound features 302.

The metal-semiconductor compound features 302 may be made of or include a metal silicide material, a silicon-germanium-metal-containing material, a germanium-metal-containing material, another suitable material, or a combination thereof. For example, the metal-semiconductor compound features 302 include TiSi, MoSi, RuSi, ZrSi, another suitable material, or a combination thereof.

In some embodiments, during the thermal operation, the epitaxial structures 138A and 138B are heated to a temperature that is in a range from about 390 degrees C. to about 440 degrees C. In some other embodiments, before the metal-containing material is applied (or deposited) on the epitaxial structures 138A and 138B, the epitaxial structures 138A and 138B are heated to be at a raised temperature. Afterwards, the epitaxial structures 138A and 138B are kept at the raised temperature while the metal-containing material is applied (or deposited). The raised temperature may be in a range from about 390 degrees C. to about 440 degrees C.

In some embodiments, while applying or depositing the metal-containing material for forming the metal-semiconductor compound features 302, the metal-containing material is also applied (or deposited) on sidewalls and bottom surfaces of the contact openings 202 to form metal layers. The metal layers may be made of or include titanium, cobalt, ruthenium, molybdenum, nickel, tantalum, tungsten, platinum, another suitable material, or a combination thereof. In some embodiments, after the formation of the metal-semiconductor compound features 302, the portions of the metal layers that are not react with the epitaxial structures 138B are removed. One or more etching processes may be used to remove the metal layers. The protective layers 204B′ and 204A may protect the dielectric layer 140 during the etching processes. In some embodiments, the protective layer 204B′ may become thinner after the etching process.

However, embodiments of the disclosure are not limited thereto. Many variations and/or modifications can be made to embodiments of the disclosure. In some other embodiments, the metal-semiconductor compound features 302 are not formed.

Afterwards, as shown in FIGS. 2J and 3O, conductive contacts 304 are formed in the contact openings 202, in accordance with some embodiments. In some embodiments, the conductive contacts 304 completely fill the remaining portions of the contact openings 202. In some embodiments, the conductive contacts 304 are closer to the semiconductor substrate 100 than the topmost surfaces of the epitaxial structures 138A and 138B, as shown in FIGS. 2J and 3O.

In some embodiments, a conductive material layer is deposited over the dielectric layer 140, the protective layer 204B′, and the metal-semiconductor compound features 302 to overfill the contact openings 202. The conductive material layer may be made of or include tungsten, ruthenium, molybdenum, cobalt, titanium, tantalum, tungsten, another suitable material, or a combination thereof. The conductive material layer may be deposited using an ALD process, a CVD process, a PVD process, an electroplating process, an electrochemical plating process, another applicable process, or a combination thereof.

Afterwards, a planarization process is used to remove the conductive material layer outside of the contact openings 202, in accordance with some embodiments. As a result, the remaining portions of the conductive material layer in the contact openings 202 form the conductive contacts 304, as shown in FIGS. 2I and 3O. The planarization process mentioned above may include a CMP process, a grinding process, an etching process, a dry polishing process, another applicable process, or a combination thereof.

As shown in FIGS. 2K and 3P, an etch stop layer 306 and a dielectric layer 308 are sequentially deposited, in accordance with some embodiments. The material and formation method of the etch stop layer 306 may be the same as or similar to those of the contact etch stop layer 139. The material and formation method of the dielectric layer 308 may be the same as or similar to those of the dielectric layer 140.

Afterwards, as shown in FIGS. 2K and 3O, conductive vias 310 and 312 are formed, in accordance with some embodiments. The conductive via 310 may penetrate through the etch stop layer 306 and the dielectric layer 308 to be electrically connected to one of the conductive contacts 304, as shown in FIGS. 2K and 3P. The conductive via 312 may penetrate through the etch stop layer 306 and the dielectric layer 308 to be electrically connected to the metal gate stack 156B, as shown in FIG. 3P. The conductive vias 310 and 312 may be made of or include copper, cobalt, tungsten, aluminum, ruthenium, another suitable material, or a combination thereof.

One or more photolithography processes and one or more etching processes may be used to form via holes used for containing the conductive vias 310 and 312. Afterwards, one or more conductive material may be formed to overfill the via holes. A planarization process may then be used to remove the portions of the conductive material outside of the via holes. As a result, the remaining portions of the conductive material form the conductive vias 310 and 312.

In some embodiments, the protective layer 204B′ protect the dielectric layer 140 during the formation of the metal-semiconductor compound features 302 and the conductive contacts 304. The positions and the profiles of the conductive contacts 304 may thus be maintained. Short circuiting and/or current leakage between the conductive contacts 304 and other conductive features nearby may thus be prevented or reduced. The protective layer 204A has a low dielectric constant. The protective layer 204A may thus help to reduce parasitic capacitance between the conductive contacts 304 and other conductive features nearby (such as the metal gate stacks 156A and 156B). As a result, the operation speed of the semiconductor device structure may be greatly improved.

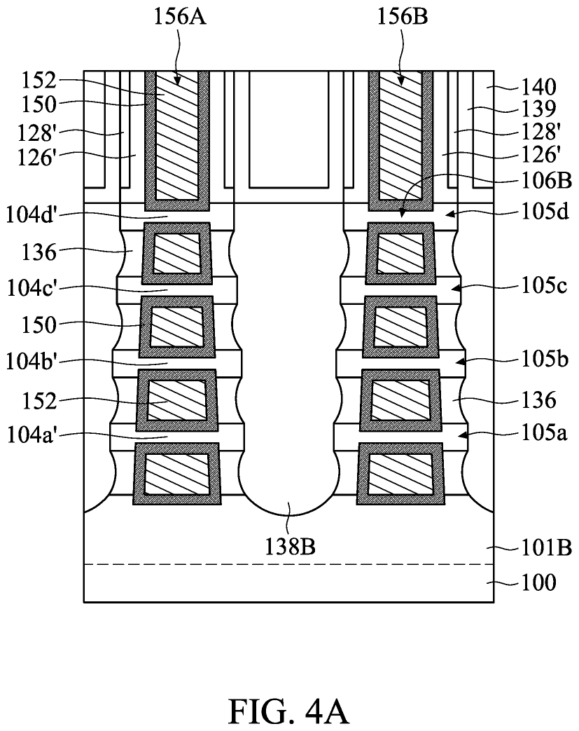

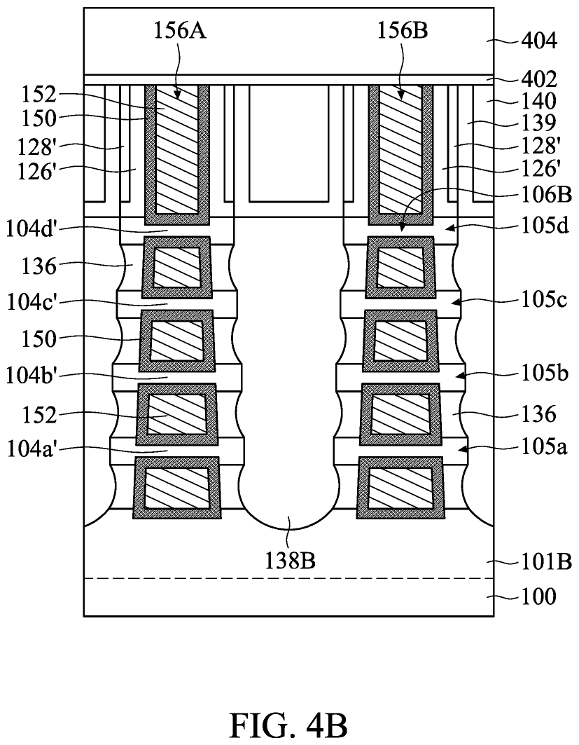

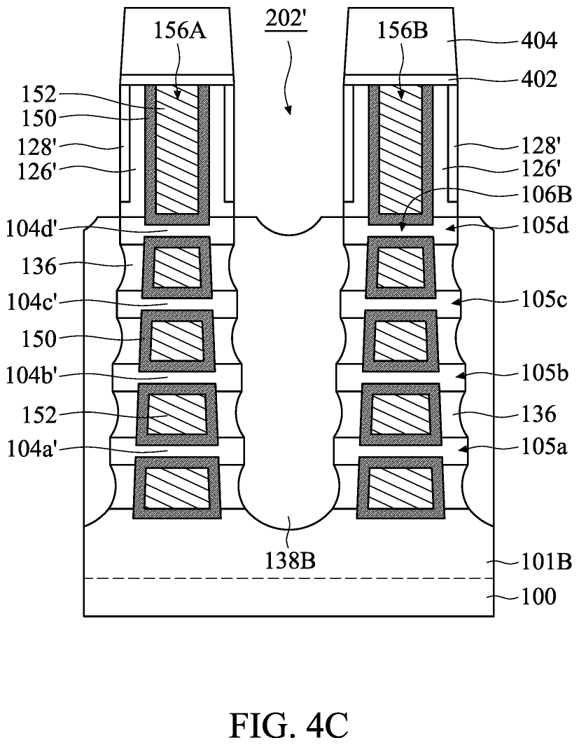

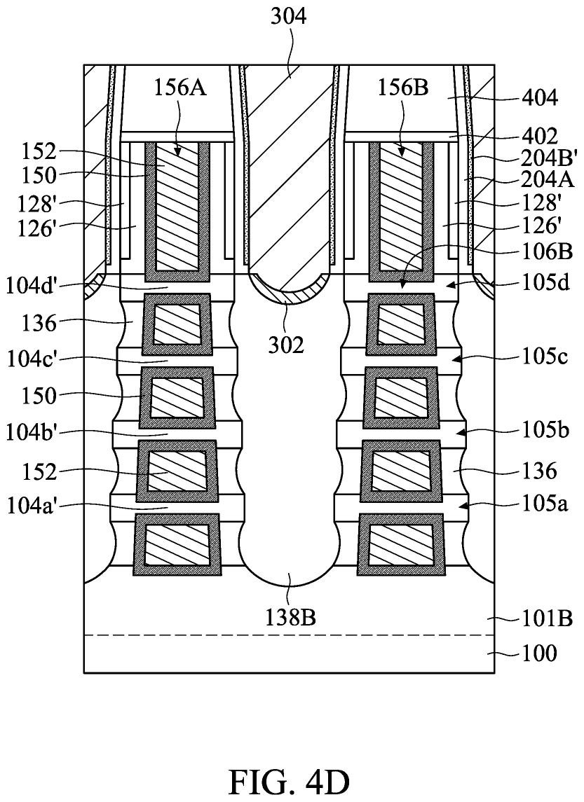

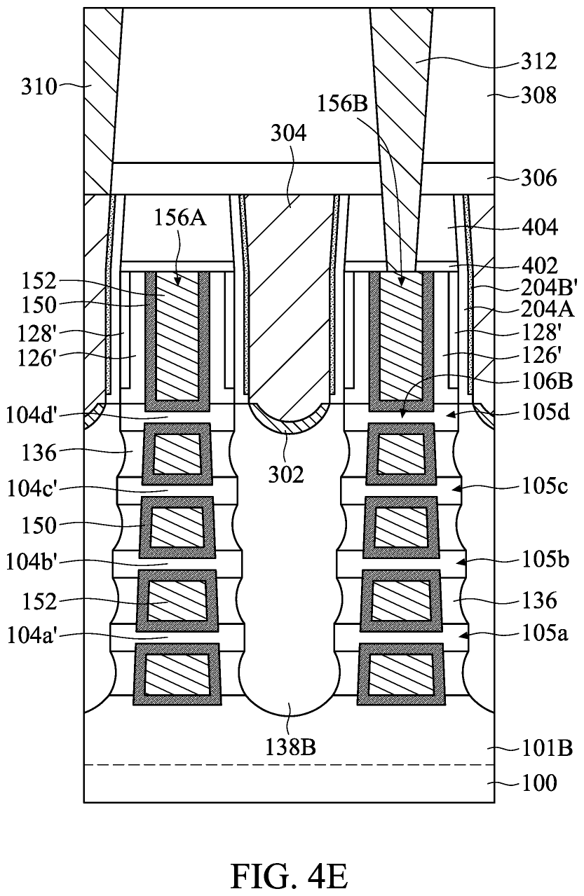

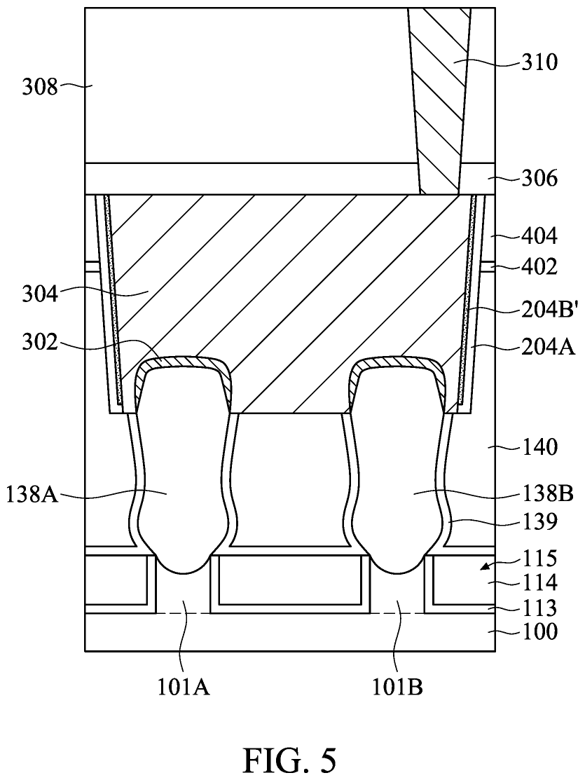

Many variations and/or modifications can be made to embodiments of the disclosure. FIGS. 4A-4E are cross-sectional views of various stages of a process for forming a portion of a semiconductor device structure, in accordance with some embodiments. FIG. 5 is a cross-sectional view of a stage of a process for forming a portion of a semiconductor device structure, in accordance with some embodiments. As shown in FIG. 4A, a structure that is the same as or similar to that shown in FIG. 3K is formed.

As shown in FIG. 4B, an etch stop layer 402 and a dielectric layer 404 are sequentially deposited over the structure shown in FIG. 4A, in accordance with some embodiments. The material and formation method of the etch stop layer 402 may be the same as or similar to those of the contact etch stop layer 139. The material and formation method of the dielectric layer 404 may be the same as or similar to those of the dielectric layer 140.

As shown in FIG. 4C, similar to the embodiments illustrated in FIGS. 2G and 3L, contact openings 202′ are formed, in accordance with some embodiments. One or more photolithography processes and one or more etching processes may be used to partially remove the contact etch stop layer 139, the dielectric layer 140, the etch stop layer 402 and the dielectric layer 404. As a result, the contact openings 202′ that penetrate through the etch stop layer 402 and the dielectric layer and expose the epitaxial structures 138A and 138B are formed.

Afterwards, as shown in FIGS. 4D and 5, the protective layers 204A and 204B′, the metal-semiconductor compound features 302, and the conductive contacts 304 are formed, in accordance with some embodiments. The process steps that are similar to those illustrated in FIGS. 2H-2J and 3M-3O may be used to form the structure shown in FIG. 4D.

Afterwards, as shown in FIGS. 4E and 5, the etch stop layer 306, the dielectric layer 308, and the conductive vias 310 and 312 are formed, in accordance with some embodiments. The process steps that are similar to those illustrated in FIGS. 2K and 3P may be used to form the structure shown in FIG. 4E.

In some embodiments, the protective layer 204B′ protect the dielectric layers 140 and 404 during the formation of the metal-semiconductor compound features 302 and the conductive contacts 304. The positions and the profiles of the conductive contacts 304 may thus be maintained. Short circuiting and/or current leakage between the conductive contacts 304 and other conductive features nearby may thus be prevented or reduced. The protective layer 204A has a low dielectric constant. The protective layer 204A may thus help to reduce parasitic capacitance between the conductive contacts 304 and other conductive features nearby (such as the metal gate stacks 156A and 156B). As a result, the operation speed of the semiconductor device structure may be greatly improved.

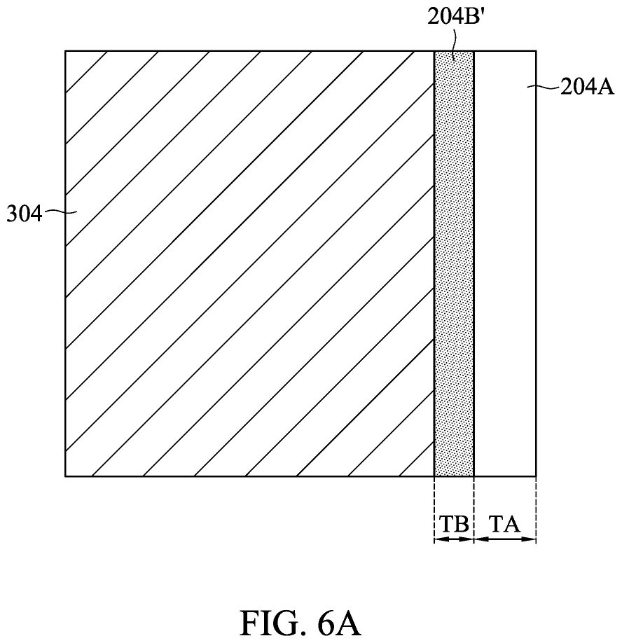

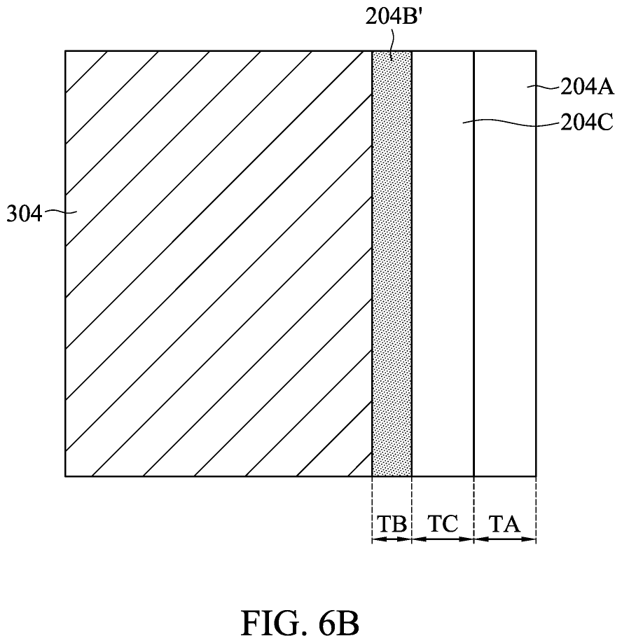

FIG. 6A is a cross-sectional view of a stage of a process for forming a portion of a semiconductor device structure, in accordance with some embodiments. FIG. 6A may shows the enlarged cross-sectional view of the structure shown in FIGS. 2K, 3P, 4E and/or 5. In some embodiments, the protective layer 204B′ is between the conductive contact 304 and the protective layer 204A. The protective layer 204A may have a thickness TA, and the protective layer 204B′ may have a thickness TB. In some embodiments, the protective layer 204A is thicker than the protective layer 204B′.

In some embodiments illustrated in FIGS. 2K, 3P, 4E, 5, and/or 6A, the protective structure has two protective layers 204A and 204B′. However, embodiments of the disclosure are not limited thereto. Many variations and/or modifications can be made to embodiments of the disclosure. In some other embodiments, the protective structure has three or more protective layers.

FIG. 6B is a cross-sectional view of a stage of a process for forming a portion of a semiconductor device structure, in accordance with some embodiments. FIG. 6B may shows the enlarged cross-sectional view of the structure shown in FIGS. 2K, 3P, 4E and/or 5. In some embodiments, a protective layer 204C is formed between the protective layers 204A and 204B′. The material and formation method of the protective layer 204C may be the same as or similar to those of the protective layer 204A. The protective layer 204C may have a thickness TC. In some embodiments, the protective layer 204C is thicker than the protective layer 204B′. In some embodiments, the thicknesses TA and TC are substantially the same. In some other embodiments, the thicknesses TA and TC are different from each other.

In some embodiments, the protective layer 204B′ has a higher dielectric constant than that of the protective layer 204C. In some embodiments, the protective layer 204B′ has a higher atomic concentration of nitrogen than that of the protective layer 204C. In some embodiments, the protective layer 204C is substantially free of nitrogen. In some embodiments, the protective layer 204C has a higher atomic concentration of oxygen than that of the protective layer 204B′.

Many variations and/or modifications can be made to embodiments of the disclosure. In some embodiments, there are four channel structures (such as the semiconductor nanostructures 104a′-104d′) formed between the nearby epitaxial structures 138B. However, embodiments of the disclosure are not limited thereto. Many variations and/or modifications can be made to embodiments of the disclosure. In some embodiments, there may be more than four semiconductor nanostructures between the nearby epitaxial structures 138B. In other embodiments, there may be fewer than four semiconductor nanostructures between the nearby epitaxial structures 138B. The total number of semiconductor nanostructures (or channel structures) between the nearby epitaxial structures 138B may be adjusted to meet requirements. For example, there may be between 2 and 10 semiconductor nanostructures between the nearby epitaxial structures 138B. The semiconductor nanostructures may have many applicable profiles. The semiconductor nanostructures may include nanosheets, nanowires, or other suitable nanostructures. Embodiments of the disclosure also include FinFET structures, forksheet structures, other suitable structures, or a combination thereof.

Embodiments of the disclosure form a semiconductor device structure with a conductive contact electrically connected to an epitaxial structure. Two or more protective layers are formed between the conductive contact and a dielectric layer laterally surrounding the conductive contact. The protective layer adjacent to the conductive contact has a better resistance to cleaning agents and/or etchants. The positions and the profiles of the conductive contact may thus be maintained. Short circuiting and current leakage between the conductive contact and other conductive features nearby may thus be prevented or reduced. The protective layer adjacent to the dielectric layer has a low dielectric constant, which may thus help to reduce parasitic capacitance between the conductive contact and other conductive features nearby (such as the metal gate stack). The operation speed of the semiconductor device structure may be greatly improved. The performance and reliability of the semiconductor device structure are thus improved.

In accordance with some embodiments, a method for forming a semiconductor device structure is provided. The method includes forming a metal gate stack wrapped around multiple semiconductor nanostructures, and the semiconductor nanostructures are adjacent to an epitaxial structure. The method also includes forming a dielectric layer over the metal gate stack and the epitaxial structure and partially removing the dielectric layer to form a contact opening exposing the epitaxial structure. The method further includes forming a first protective layer over sidewalls of the contact opening and forming a second protective layer over the first protective layer. The first protective layer has a lower dielectric constant than that of the second protective layer. In addition, the method includes forming a conductive contact over the second protective layer and the epitaxial structure to fill the contact opening.

In accordance with some embodiments, a method for forming a semiconductor device structure is provided. The method includes forming an epitaxial structure beside a channel structure and forming a dielectric layer surrounding and covering the epitaxial structure. The method also includes partially removing the dielectric layer to form a contact opening exposing the epitaxial structure and forming a protective structure over sidewalls of the contact opening. The protective structure has an inner portion and an outer portion, and the inner portion is between the outer portion and the dielectric layer. The outer portion has a higher atomic concentration of nitrogen than that of the inner portion. The method further includes forming a conductive contact filling the contact opening.

In accordance with some embodiments, a semiconductor device structure is provided. The semiconductor device structure includes multiple semiconductor nanostructures and an epitaxial structure adjacent to the semiconductor nanostructures. The semiconductor device structure also includes a conductive contact electrically connected to the epitaxial structure and a dielectric layer laterally surrounding the epitaxial structure and the conductive contact. The semiconductor device structure further includes a first protective layer between the dielectric layer and the conductive contact and a second protective layer between the first protective layer and the conductive contact. The first protective layer has a lower dielectric constant than that of the second protective layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a metal gate stack wrapped around a plurality of semiconductor nanostructures, wherein the semiconductor nanostructures are adjacent to an epitaxial structure;
forming a dielectric layer over the metal gate stack and the epitaxial structure;
partially removing the dielectric layer to form a contact opening exposing the epitaxial structure;
forming a first protective layer over sidewalls of the contact opening;
forming a second protective layer over the first protective layer, wherein the first protective layer has a lower dielectric constant than that of the second protective layer; and
forming a conductive contact over the second protective layer and the epitaxial structure to fill the contact opening.

2. The method for forming a semiconductor device structure as claimed in claim 1, further comprising:
forming a metal-semiconductor compound feature on the epitaxial structure after the second protective layer is formed, wherein the metal-semiconductor compound feature is between the conductive contact and the epitaxial structure.

3. The method for forming a semiconductor device structure as claimed in claim 2, further comprising:
cleaning an exposed surface of the epitaxial structure after the second protective layer is formed and before the metal-semiconductor compound feature is formed.

4. The method for forming a semiconductor device structure as claimed in claim 3, wherein the second protective layer is at least partially consumed during the cleaning of the exposed surface of the epitaxial structure.

5. The method for forming a semiconductor device structure as claimed in claim 1, wherein the second protective layer has a higher atomic concentration of nitrogen than that of the first protective layer.

6. The method for forming a semiconductor device structure as claimed in claim 1, wherein the first protective layer is thicker than the second protective layer.

7. The method for forming a semiconductor device structure as claimed in claim 1, further comprising:
forming a gate spacer over a sidewall of a dummy gate stack; and
replacing the dummy gate stack with the metal gate stack, wherein the first protective layer is in direct contact with the gate spacer and the dielectric layer.

8. The method for forming a semiconductor device structure as claimed in claim 1, further comprising:
forming a second dielectric layer over the metal gate stack and the conductive contact; and
forming a conductive via penetrating through the second dielectric layer and electrically connected to the conductive contact.

9. The method for forming a semiconductor device structure as claimed in claim 1, further comprising:
forming a second dielectric layer over the metal gate stack and the dielectric layer; and
partially removing the second dielectric layer and the first dielectric layer to form the contact opening.

10. The method for forming a semiconductor device structure as claimed in claim 9, further comprising:
forming a third dielectric layer over the second dielectric layer and the conductive contact; and
forming a conductive via penetrating through the third dielectric layer and electrically connected to the conductive contact.

11. A method for forming a semiconductor device structure, comprising:
forming an epitaxial structure beside a channel structure;
forming a dielectric layer surrounding and covering the epitaxial structure;
partially removing the dielectric layer to form a contact opening exposing the epitaxial structure;
forming a protective structure over sidewalls of the contact opening, wherein the protective structure has an inner portion and an outer portion, the inner portion is between the outer portion and the dielectric layer, and the outer portion has a higher atomic concentration of nitrogen than that of the inner portion; and
forming a conductive contact filling the contact opening.

12. The method for forming a semiconductor device structure as claimed in claim 11, further comprising:
forming a metal-semiconductor compound feature on the epitaxial structure after the protective structure is formed, wherein the metal-semiconductor compound feature is between the conductive contact and the epitaxial structure.

13. The method for forming a semiconductor device structure as claimed in claim 12, wherein the metal-semiconductor compound feature is formed before the conductive contact is formed.

14. The method for forming a semiconductor device structure as claimed in claim 12, further comprising:
cleaning the epitaxial structure before the metal-semiconductor compound feature is formed, wherein the protective structure becomes thinner after the cleaning of the epitaxial structure.

15. The method for forming a semiconductor device structure as claimed in claim 11, wherein the inner portion of the protective structure has a lower dielectric constant than that of the outer portion of the protective structure.

16. A semiconductor device structure, comprising:
a plurality of semiconductor nanostructures;
an epitaxial structure adjacent to the semiconductor nanostructures;
a conductive contact electrically connected to the epitaxial structure;
a dielectric layer laterally surrounding the epitaxial structure and the conductive contact;
a first protective layer between the dielectric layer and the conductive contact; and
a second protective layer between the first protective layer and the conductive contact, wherein the first protective layer has a lower dielectric constant than that of the second protective layer.

17. The semiconductor device structure as claimed in claim 16, further comprising:
a metal-semiconductor compound feature between the epitaxial structure and the conductive contact.

18. The semiconductor device structure as claimed in claim 16, wherein the first protective layer is thicker than the second protective layer.

19. The semiconductor device structure as claimed in claim 16, further comprising:
a third protective layer between the first protective layer and the second protective layer, wherein the second protective layer has a higher dielectric constant than that of the third protective layer.

20. The semiconductor device structure as claimed in claim 19, wherein the second protective layer has a higher atomic concentration of nitrogen than that of the third protective layer.
